(19) United States
(12) Patent Application Publication
(10) Pub. No.: US 2023/0266070 A1
(43) Pub. Date: Aug. 24, 2023

(54) ADDITIVELY MANUFACTURED HEAT DISSIPATION DEVICE

(71) Applicant: Intel Corporation, Santa Clara, CA (US)

(72) Inventors: Feras Eid, Chandler, AZ (US); Akhilesh Rallabandi, Chandler, AZ (US)

(73) Assignee: Intel Corporation, Santa Clara, CA (US)

(21) Appl. No.: 17/677,829

(22) Filed: Feb. 22, 2022

(51) Int. Cl. F28D 15/04; F28D 15/02; H05K 7/20

(52) U.S. Cl. CPC F28D 15/046; F28D 15/043; F28D 15/0275; H05K 7/20336

(57) ABSTRACT

A heat dissipation device for an integrated circuit assembly may be fabricated to include at least one heat pipe that is at least partially embedded in a base plate that is formed with an additive manufacturing process, such as cold spraying. Embedding the at least one heat pipe in the base plate, rather than soldering the heat pipe to the base plate, eliminates the thermal bottleneck presented by the soldering material and reduces the overall height or thickness of the integrated circuit assembly.

### TECHNICAL FIELD

Embodiments of the present description generally relate to the removal of heat from integrated circuit devices, and, more particularly, to thermal management solutions wherein a heat dissipation device may include an additively manufactured base plate having at least one heat pipe at least partially embedded therein.

### BACKGROUND

The integrated circuit industry is continually striving to produce ever faster, smaller, and thinner integrated circuit (IC) devices and packages for use in various electronic products, including, but not limited to, computer servers and portable products, such as portable computers, electronic tablets, cellular phones, digital cameras, and the like.

As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. Thus, heat dissipation devices are used to remove heat from the integrated circuit devices in an integrated circuit package. In one example, as shown in FIGS. 1 and 2, at least one integrated circuit device 120 may be mounted to an electronic substrate 110 and a heat dissipation structure 130 may be thermally attached to the at least one integrated circuit device 120, thereby forming an electronic assembly 100. The heat dissipation structure 130 may include at least one heat pipe 140, wherein the at least one heat pipe 140 may convey heat away from the integrated circuit device 120 to an external heat sink 150 (illustrated as a plurality of fin structures). As will be understood to those skilled in the art, the heat pipe(s) 140, as shown in FIG. 2, may comprise at least one tube 142 having an exterior surface 144, an interior surface 146, a wicking material 148 abutting the interior surface 146, and a working fluid (not specifically illustrated), wherein the working fluid transfers heat by vaporizing near the integrated circuit device 120, condensing near the external heat sink 150 (see FIG. 1), and returning from the external heat sink 150 (see FIG. 1) through the wicking material 148. The structures and mechanisms of heat pipes are well known in the art and for the purposes of clarity and conciseness will not be described in detail.

The heat dissipation device 130 may further a base plate 160 that may be attached to the at least one heat pipe 140. The base plate 160 may be thermally attached to the at least one integrated circuit device 120 with a thermal interface material disposed 170 therebetween. The thermal interface material 170 may include thermal greases, gap pads, polymers, and the like. The base plate 160 is typically made of a high thermal conductivity material, such as copper. As will be understood, the base plate 160 may improve structural rigidity of the heat dissipation device 130 and may assist in spreading heat laterally beyond the footprint of the at least one integrated circuit device 120 to increase the effective area of the hot interface of the at least one heat pipe 140.

As further shown in FIG. 1, the at least one heat pipe 130 may be soldered or brazed to the base plate 160 with a solder material 180. However, the solder material 180 generally has a thermal conductivity that is lower than either the base plate 160 or the at least one heat pipe 140. Therefore, the solder material 180 may pose a thermal bottleneck in the transfer of heat away from the at least on integrated circuit device 120. Overcoming such thermal bottlenecks to reduce thermal resistance between the at least one integrated circuit device 120 and the heat dissipation device 130 would be commercially advantageous.

Additionally, the thickness T (z-direction) of the combination of the base plate 160, the solder material 180, and the at least one heat pipe 130 may be substantial. Thus, reducing the thickness T would assist in the goal of producing thinner electronic devices.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly in accordance with conventional assemblies.

FIG. 2 is a side cross-sectional views of an integrated circuit assembly along line 2-2 of FIG. 1 in accordance with conventional assemblies.

FIG. 3 is a side cross-sectional view of an integrated circuit assembly, according to an embodiment of the present description.

FIG. 4 is a side cross-sectional views of an integrated circuit assembly along line 4-4 of FIG. 3, according to an embodiment of the present description.

FIGS. 5-9 are side cross-sectional views of a process of forming a heat dissipation device, according to various embodiments of the present description.

FIG. 10 is a flow chart of a process of fabricating an integrated circuit package, according to one embodiment of the present description.

FIG. 11 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description relate to the formation of an additively manufactured heat dissipation device, wherein the heat dissipation device includes at least one heat pipe at least partially embedded in a base plate that is formed with an additive manufacturing process, such as cold spraying.

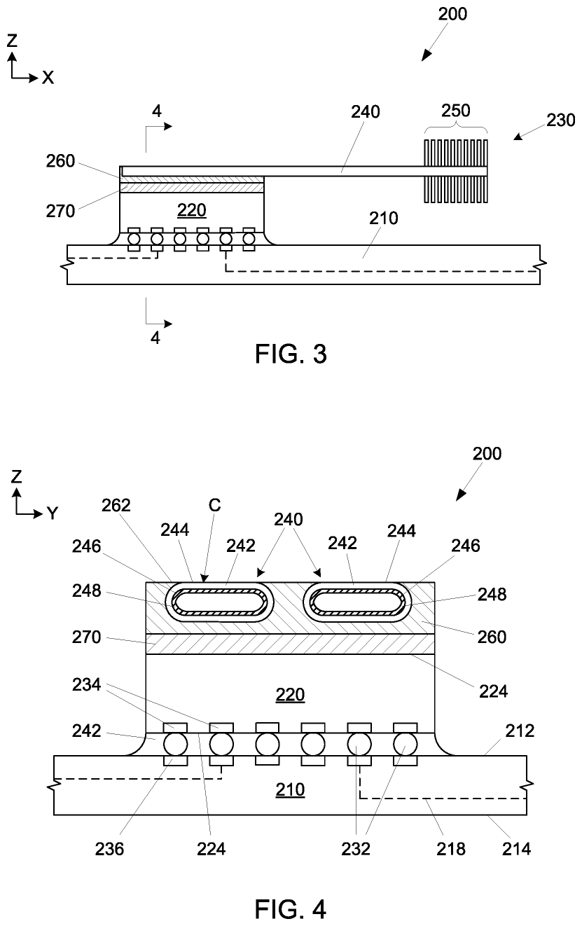

FIGS. 3 and 4 illustrate an integrated circuit assembly 200 having at least one integrated circuit device 220 electrically attached to an electronic substrate 210 in a configuration generally known as a flip-chip or controlled collapse chip connection (“C4”) configuration, according to an embodiment of the present description.

The electronic substrate 210 may be any appropriate structure, including, but not limited to, an interposer. The electronic substrate 210 may have a first surface 212 and an opposing second surface 214. The electronic substrate 210 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The electronic substrate 210 may further include conductive routes 218 (shown in dashed lines) extending through the electronic substrate 210. As will be understood to those skilled in the art, the conductive routes 218 may be a combination of conductive traces (not shown) and conductive vias (not shown) extending through the plurality of dielectric material layers (not shown). These conductive traces and conductive vias are well known in the art and are not shown in FIGS. 3 and 4 for purposes of clarity and conciseness. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 210 may be a cored substrate or a coreless substrate. In one embodiment of the present description, the electronic substrate 210 may comprise a silicon or glass interposer. In another embodiment of the present description, the electronic substrate 210 may include active and/or passive devices.

The integrated circuit device 220 may be any appropriate device, including, but not limited to, a microprocessor, a chipset, a graphics device, a wireless device, a memory device, an application specific integrated circuit, combinations thereof, stacks thereof, or the like. Furthermore, the integrated circuit device 220 may be a monolithic die or a die stack that can consist of two or more vertical levels of dice stacked on top of each other, and may include additional materials, such as a mold compound, between at least two of the dice. As shown, the integrated circuit device 220 may each have a first surface 222 and an opposing second surface 224.

In an embodiment of the present description, the integrated circuit device 220 may be electrically attached to the electronic substrate 210 with a plurality of device-to-substrate interconnects 232. In one embodiment of the present description, the device-to-substrate interconnects 232 may extend between bond pads 236 on the first surface 212 of the electronic substrate 210 and bond pads 234 on the first surface 222 of the integrated circuit device 220. The device-to-substrate interconnects 232 may be any appropriate electrically conductive material or structure, including, but not limited to, solder balls, metal bumps or pillars, metal filled epoxies, or a combination thereof. In one embodiment, the device-to-substrate interconnects 232 may be solder balls formed from tin, lead/tin alloys (for example, 63% tin/37% lead solder), and high tin content alloys (e.g., 90% or more tin—such as tin/bismuth, eutectic tin/silver, ternary tin/silver/copper, eutectic tin/copper, and similar alloys). In another embodiment, the device-to-substrate interconnects 232 may be copper bumps or pillars. In a further embodiment, the device-to-substrate interconnects 232 may be metal bumps or pillars coated with a solder material. In still a further embodiment, the device-to-substrate interconnects 232 may be anisotropic conductive film.

The bond pads 234 may be in electrical communication with integrated circuitry (not shown) within the integrated circuit device 220. The bond pads 236 on the first surface 212 of the electronic substrate 210 may be in electrical contact with the conductive routes 218. When the electronic substrate 210 is an interposer, the conductive routes 218 may extend through the electronic substrate 210 and be connected to bond pads (not shown) on the second surface 214 of the electronic substrate 210, wherein external interconnects (not shown) may be disposed on the bond pads (not shown) on the second surface 214 of the electronic substrate 210. The external interconnects (not shown) may be any appropriate electrically conductive material, such as those discussed with regard to the device-to-substrate interconnects 232, as previously discussed.

An electrically-insulating underfill material 242, such as an epoxy material, may be disposed between the integrated circuit device 220 and the electronic substrate 210. The underfill material 242 may be used to overcome the mechanical stress issues that can arise from thermal expansion mismatch between the electronic substrate 210 and the integrated circuit device 220. As will be understood to those skilled in the art, the underfill material 242 may be dispensed between the first surface 222 of the integrated circuit device 220 and the electronic substrate 210 as a viscous liquid and then hardened with a curing process.

As further shown in FIGS. 3 and 4, the integrated circuit assembly 200 may further include a heat dissipation device 230 thermally attached with the second surface 224 of the integrated circuit device 220 with a thermal interface material 280. The heat dissipation device 230 may comprise at least one heat pipe 240 at least partially embedded in a base plate 260, wherein the at least one heat pipe 240 may convey heat away from the integrated circuit device 220 to an external heat sink 290 (illustrated as a plurality of fin structures). In one embodiment of the present description, the at least one heat pipe 240 may comprise at least one tube 242 having an exterior surface 244, an interior surface 246, a wicking material 248 abutting the interior surface 246, and a working fluid (not specifically illustrated) disposed within the heat pipe 240, wherein the working fluid transfers heat by vaporizing near the integrated circuit device 220, condensing near the external heat sink 250 (see FIG. 3), and returning from the external heat sink 290 through the wicking material 248. The structures and mechanisms of heat pipes are well known in the art and for the purposes of clarity and conciseness will not be described in detail.

As will be understood, the base plate 260 may improve structural rigidity of the heat dissipation device 230. Additionally, although the base plate 260 is shown to substantially match the footprint, it may extend beyond the footprint of the at least one integrated circuit device 210, which may assist in spreading heat laterally to increase the effective area of the hot interface of the at least one heat pipe 240.

As shown in FIG. 4, the at least one heat pipe 240 may be at least partially embedded within the base plate 260. In one embodiment of the present description, on at least a portion of the heat pipe 240, the base plate 260 contacts between about 60 and 90 percent of a circumference C (relative to the z-y plane) of the exterior surface 244 of the at least one heat pipe 240. In another embodiment of the present description, at least a portion of the exterior surface 244 of the at least one heat pipe 240 is substantially planar with an outer surface 262 for the base plate 260.

In various embodiments of the present description, the base plate 270 may be any appropriate, thermally conductive material, including, but not limited to, copper, nickel, aluminum, silver, gold, diamond, aluminum nitride, silicon carbide, combinations thereof, and the like.

The base plate 260 may be formed by an additive process, such as high throughput additive manufacturing (“HTAM”). In one embodiment, the base plate 260 may be formed with a “coldspray” HTAM process. As the coldspray process is known in the art, it will not be illustrated, but rather merely discussed herein. With a coldspray process, solid powders of a desired material or materials to be deposited are accelerated in a carrier jet (e.g., compressed air or nitrogen) by passing the jet through a nozzle, such as a converging diverging nozzle. The jet exits the nozzle at a high velocity and reaches an underlying substrate, where the impact causes the solid particles in the jet to plastically deform and bond to the substrate. The nozzle is moved repeatedly over the deposited material to form subsequent layers of the material similarly adhered to each underlying layer upon continued jet impact, producing fast buildup (e.g., layers that are a few hundred microns thick can be deposited over an area of about 100-1000 mm² in a few seconds). Moreover, unlike thermal spraying techniques, this approach does not require melting the particles, thus protecting both the powders and the substrate from experiencing excessive processing temperatures. Because additive manufacturing, such as coldspray, is used, it eliminates the need for using lithography and the many steps associated with it (resist deposition, exposure, resist development, and resist removal) that are characteristic of subtractive or semi-additive methods, such as plating, sputtering, and the like. Additionally, 3D topography can be easily created, if needed, as will be understood to those skilled in the art. Moreover, different materials can be combined in the feed powder and used to create hybrid features in one step.

As shown in FIGS. 3 and 4, the base plate 260 may be thermally attached to the second surface 224 of the at least one integrated circuit device 220 with a thermal interface material disposed 270 therebetween. In various embodiments of the present description, the thermal interface material 270 may be any appropriate, thermally conductive material, including, but not limited to, a thermal grease, a thermal gap pad, a polymer, an epoxy filled with high thermal conductivity fillers, such as metal particles or silicon particles, and the like. In one embodiment of the present description, the thermal interface material 270 may be a phase change material. A phase change material is a substance with a high heat of fusion, which, when it melts and solidifies, is capable of storing and releasing large amounts of thermal energy. In an embodiment of the present description, the phase change material may include, but not limited to, nonadecane, decanoic (capric) acid, eicosane, dodecanoic (lauric) acid, docosane, paraffin wax, stearic acid, tetradecanoic (myristic) acid, octadecanol, hexadecanoic (palmitic) acid, and metallic alloys which include one or more of bismuth, lead, tin, cadmium, antimony, indium, thallium, tellurium, selenium, gallium, mercury, and combinations thereof.

The embodiment of the present description may have distinct advantages with regard to heat dissipation solutions for integrated circuit devices. First, in systems where an integrated circuit device stack, such as a central processing unit (CPU) stack, is in the thickness critical path, the embodiment of the present description may allow for a direct reduction in system thickness. Thus, a thinner CPU stack may also be utilized to allow for a larger air-gap between hot components and a chassis of the CPU, which may result in a lower skin temperature potential, as will be understood to those skilled in the art. Second, for systems which are thermally constrained, the embodiments of the present description may be used to accommodate thicker/larger heat pipes. A thicker/larger heat pipe will allow for improved thermal dissipation while maintaining the same system thickness (as it will tolerate a larger quantum of heat input prior to drying out), as will also be understood to those skilled in the art.

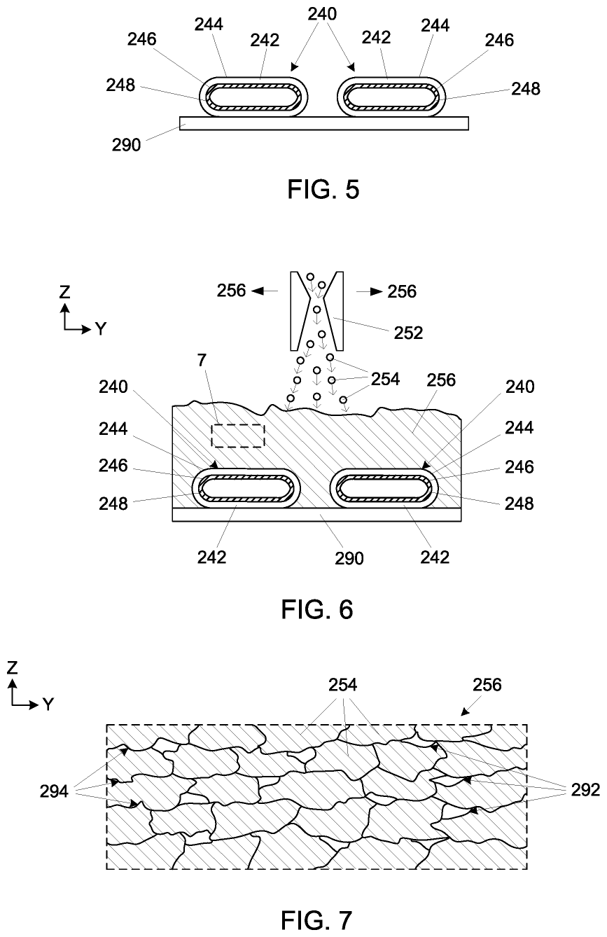

FIGS. 5-9 illustrate a method of fabricating an embodiment of the present description. As shown in FIG. 5, at least one heat pipe 240 may be positioned on a foundation substrate 290. In one embodiment of the present description, the at least one heat pipe 240 may be attached to the foundation substrate 290. In an embodiment of the present description, the foundation substrate 290 may have a thickness of less than 50 microns. In another embodiment of the present description, when the foundation substrate 290 is to be removed from the final assembly, it may be any appropriate rigid material. In a further embodiment of the present description, when the foundation substrate 290 is to remain in the final assembly, it may be thermally conductive material, including, but not limited to, copper, nickel, titanium, alloys thereof, and the like.

As shown in FIG. 6, a thermally conductive material 254 may be deposited on the foundation substrate 290. The thermally conductive material 254 may be deposited by a cold spray process, as previously discussed, wherein the thermally conductive material (shown as thermally conductive material particles with arrows 254 and as a deposited thermally conductive material mass 256) is sprayed through a nozzle 252 (such as a convergent/divergent nozzle) onto the foundation substrate 290 and the at least one heat pipe 240. The nozzle 252 may be moved (shown as arrows 258) across the foundation substrate 290 and the at least one heat pipe 240 during the deposition process.

FIG. 7 illustrates the inset 7 in FIG. 6 and further illustrates deposition of thermally conductive material particles 254 to form the thermally conductive material mass 256, in accordance with some embodiments of HTAM process, as previously discussed. As shown, the microstructure of heat thermally conductive material mass 256 comprises deformed thermally conductive material particles 254 in layered in a lamellar structure/manner and voids 292. At sufficient magnification, boundaries 294 between the thermally conductive material particles 254 are apparent, as distinguished from atomic deposition processes, such as plating. The lamellar structure of the thermally conductive material particles 254 may be evident within the thermally conductive material mass 256, which are indicative of the impact between the thermally conductive material particles 254 and the foundation substrate 290, between thermally conductive material particles 254 and the at least one heat pipe 240, and between the thermally conductive material particles 254 and the previous deposited thermally conductive material particles 254, where most of the thermally conductive material particles 254 plastically deform and flatten. In some embodiments, individual deformed thermally conductive material particles 254 are delineated by discernable boundaries 294, which may be observed under magnification. In other embodiments, the boundaries 294 may not be apparent at even under high magnification.

Because thermally conductive material particles 254 may have irregular shapes, voids 292 can appear at the boundaries 294 between the thermally conductive material particles 254. As such, the thermally conductive material mass 256 (as well as the base plate 260 to be formed therefrom) will be somewhat porous. The porosity may be expressed as % voiding area (as measured from a cross sectional micrograph within the x-z plane illustrated in FIG. 7). The microstructure of materials formed by cold spray, thermal spray, or a similar HTAM process, may have larger void area percentages than materials having substantially the same composition formed by other techniques. Voiding area percentage is a quality control parameter that can be monitored in spray deposition processes. While bulk material, and thin film materials deposited by other means (e.g., atomic techniques), typically have void areas of zero, materials deposited by HTAM processes (e.g., cold spray) may have void areas ranging from 0.1% to 0.5%, or more. Hence, the existence of voids 292 is indicative of subsequently formed base plate 260 having been formed by an HTAM process, such as spray deposition (e.g., a cold spray process).

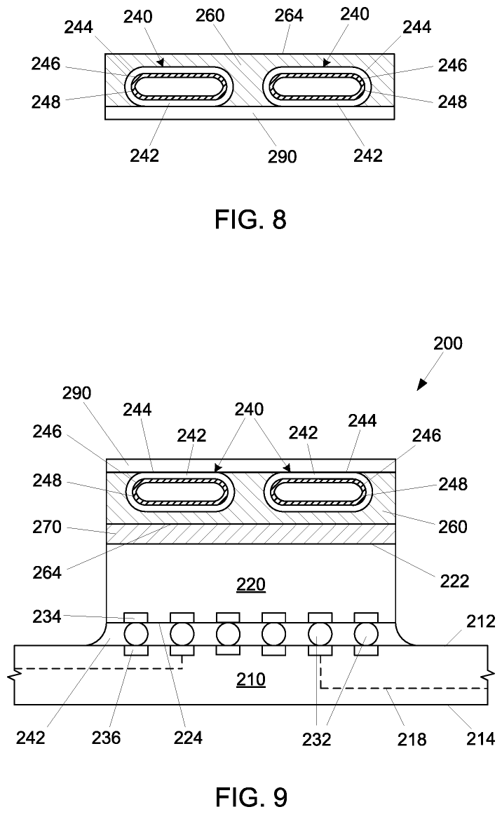

As will be understood to those skilled in the art, the deposition of the thermally conductive material 254 (see FIG. 6) using high throughput additive manufacturing, such as coldspray, creates a relatively rough surface to the thermally conductive material mass 256 (see FIG. 6). Thus, the thermally conductive material mass 256 (see FIG. 6) may be polished (such as grinding, chemical mechanical planarization, or other such polishing techniques) to form the base plate 260 and a planarized surface 262 thereof, as shown in FIG. 8.

As shown in FIG. 9, the assembly shown in FIG. 8 may be flipped and the planarized surface 262 of the base plate 260 may be brought into thermal contact with the integrated circuit device 220 with the thermal interface material 270 to form the integrated circuit assembly 200. Optionally, the foundation substrate 290 may be removed to form the integrated circuit assembly 200 of FIG. 4.

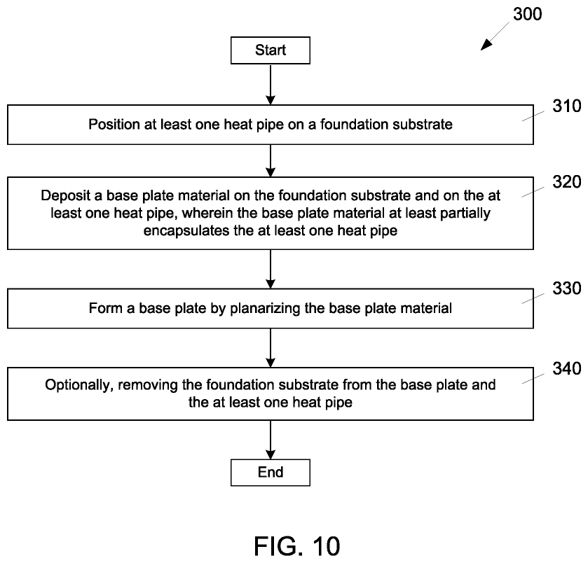

FIG. 10 is a flow chart of a process 300 of fabricating a heat dissipation device according to an embodiment of the present description. As set forth in block 310, at least one heat pipe may be positioned on a foundation substrate. A base plate material may be deposited on the foundation substrate and the at least one heat pipe, wherein the base plate material at least partially encapsulates the at least one heat pipe, as set forth in block 320. As set forth in block 330, a base plate may be formed by planarizing the base plate material. Optionally, the foundation substrate may be removed from the base plate and the at least one heat pipe, as set forth in block 340.

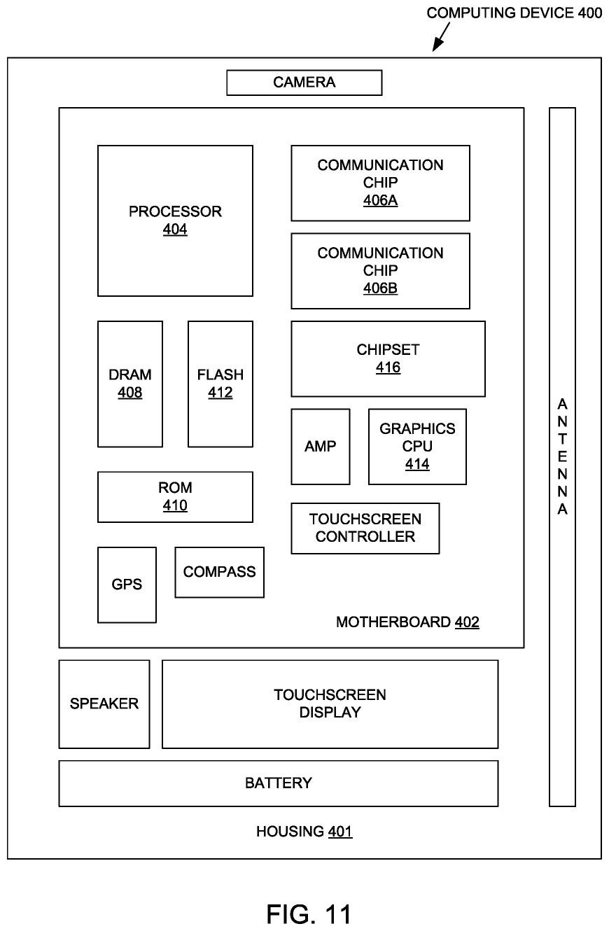

FIG. 11 illustrates an electronic or computing device 400 in accordance with one implementation of the present description. The computing device 400 may include a housing 401 having a board 402 disposed therein. The computing device 400 may include a number of integrated circuit components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 402. In some implementations, at least one of the integrated circuit components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include a heat dissipation device comprising at least one heat pipe and a base plate comprising a base plate material, wherein the base plate material at least partially encapsulates the at least one heat pipe.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

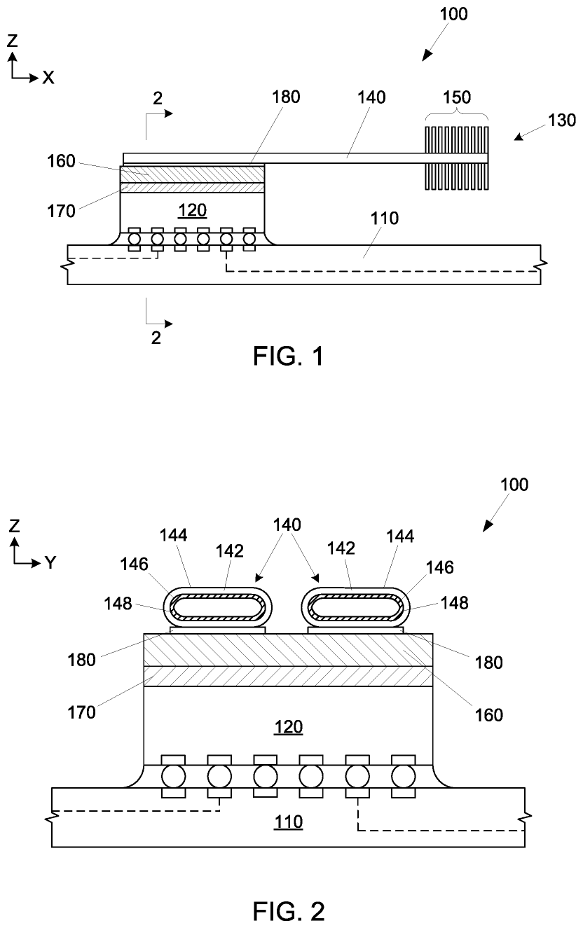

It is understood that the subject matter of the present description is not necessarily limited to specific applications illustrated in FIGS. 1-11. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein Example 1 is an apparatus comprising at least one heat pipe and a base plate comprising a base plate material, wherein the base plate material at least partially encapsulates the at least one heat pipe.

In Example 2, the subject matter of Example 1 can optionally include a foundation substrate contacting the at least one heat pipe and contacting the at least one base plate.

In Example 3, the subject matter of any of Example 1 to 2 can optionally include the at least one heat pipe including an exterior surface having a circumference, wherein on at least a portion of the at least one heat pipe, the base plate material contacts between about 60 and 90 percent of the circumference of the exterior surface of the at least one heat pipe on at least a portion thereof.

In Example 4, the subject matter of any of Example 1 to 3 can optionally include the base plate including an outer surface and wherein at least a portion of the exterior surface of the at least one heat pipe is substantially planar with the outer surface for the base plate.

In Example 5, the subject matter of any of Examples 1 to 4 can optionally include the base plate material being a thermally conductive material.

Example 6 is a method comprising positioning at least one heat pipe on a foundation substrate; depositing a base plate material on the foundation substrate and the at least one heat pipe, wherein the base plate material at least partially encapsulates the at least one heat pipe; and forming a base plate may be formed by planarizing the base plate material.

In Example 7, the subject matter of Example 6 can optionally include removing the foundation substrate from the base plate and the at least one heat pipe.

In Example 8, the subject matter of Example 6 to 7 can optionally include depositing the base plate material comprises cold spray depositing the base plate material.

Example 9 is an apparatus comprising an electronic substrate having a first surface and an opposing second surface; an integrated circuit device having a first surface and an opposing second surface, wherein the first surface of the integrated circuit device is electrically attached to the first surface of the electronic substrate; and a heat dissipation device thermally attached to the second surface of the integrated circuit device, wherein the heat dissipation device comprises at least one heat pipe; and a base plate comprising a base plate material, wherein the base plate material at least partially encapsulates the at least one heat pipe.

In Example 10, the subject matter of Example 9 can optionally include a foundation substrate contacting the at least one heat pipe and contacting the at least one base plate.

In Example 11, the subject matter of any of Example 9 to 10 can optionally include the at least one heat pipe including an exterior surface having a circumference, wherein on at least a portion of the at least one heat pipe, the base plate material contacts between about 60 and 90 percent of the circumference of the exterior surface of the at least one heat pipe on at least a portion thereof.

In Example 12, the subject matter of any of Example 9 to 11 can optionally include the base plate including an outer surface and wherein at least a portion of the exterior surface of the at least one heat pipe is substantially planar with the outer surface for the base plate.

In Example 13, the subject matter of any of Examples 9 to 12 can optionally include the base plate material being a thermally conductive material.

In Example 14, the subject matter of any of Examples 9 to 13 can optionally include a thermal interface material between the second surface of the integrated circuit device and the base plate of the heat dissipation device.

Example 15 is an electronic system comprising an electronic board and an integrated circuit assembly attached to the electronic board, wherein the integrated circuit assembly comprises an electronic substrate having a first surface and an opposing second surface; and an integrated circuit device having a first surface and an opposing second surface, wherein the first surface of the integrated circuit device is electrically attached to the first surface of the electronic substrate; and a heat dissipation device thermally attached to the second surface of the integrated circuit device, wherein the heat dissipation device comprises at least one heat pipe; and a base plate comprising a base plate material, wherein the base plate material at least partially encapsulates the at least one heat pipe.

In Example 16, the subject matter of Example 15 can optionally include a foundation substrate contacting the at least one heat pipe and contacting the at least one base plate.

In Example 17, the subject matter of any of Example 15 to 16 can optionally include the at least one heat pipe including an exterior surface having a circumference, wherein on at least a portion of the at least one heat pipe, the base plate material contacts between about 60 and 90 percent of the circumference of the exterior surface of the at least one heat pipe on at least a portion thereof.

In Example 18, the subject matter of any of Example 15 to 17 can optionally include the base plate including an outer surface and wherein at least a portion of the exterior surface of the at least one heat pipe is substantially planar with the outer surface for the base plate.

In Example 19, the subject matter of any of Examples 15 to 18 can optionally include the base plate material being a thermally conductive material.

In Example 20, the subject matter of any of Examples 15 to 19 can optionally include a thermal interface material between the second surface of the integrated circuit device and the base plate of the heat dissipation device.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus, comprising:
at least one heat pipe; and
a base plate comprising a base plate material, wherein the base plate material at least partially encapsulates the at least one heat pipe.

2. The apparatus of claim 1, further comprising a foundation substrate contacting the at least one heat pipe and contacting the at least one base plate.

3. The apparatus of claim 1, wherein the at least one heat pipe includes an exterior surface having a circumference, wherein on at least a portion of the at least one heat pipe, the base plate material contacts between about 60 and 90 percent of the circumference of the exterior surface of the at least one heat pipe on at least a portion thereof.

4. The apparatus of claim 1, wherein the base plate includes an outer surface and wherein at least a portion of the exterior surface of the at least one heat pipe is substantially planar with the outer surface for the base plate.

5. The apparatus of claim 1, wherein the base plate material is a thermally conductive material.

6. A method comprising:
positioning at least one heat pipe on a foundation substrate;
depositing a base plate material on the foundation substrate and the at least one heat pipe, wherein the base plate material at least partially encapsulates the at least one heat pipe; and
forming a base plate may be formed by planarizing the base plate material.

7. The method of claim 6, further comprising removing the foundation substrate from the base plate and the at least one heat pipe.

8. The method of claim 6, wherein depositing the base plate material comprises cold spray depositing the base plate material.

9. An apparatus, comprising:
an electronic substrate having a first surface;
an integrated circuit device having a first surface and an opposing second surface, wherein the first surface of the integrated circuit device is electrically attached to the first surface of the electronic substrate; and
a heat dissipation device thermally attached to the second surface of the integrated circuit device, wherein the heat dissipation device comprises at least one heat pipe, and a base plate comprising a base plate material, wherein the base plate material at least partially encapsulates the at least one heat pipe.

10. The apparatus of claim 9, further comprising a foundation substrate contacting the at least one heat pipe and contacting the at least one base plate.

11. The apparatus of claim 9, wherein the at least one heat pipe includes an exterior surface having a circumference, wherein on at least a portion of the at least one heat pipe, the base plate material contacts between about 60 and 90 percent of the circumference of the exterior surface of the at least one heat pipe on at least a portion thereof.

12. The apparatus of claim 9, wherein the base plate includes an outer surface and wherein at least a portion of the exterior surface of the at least one heat pipe is substantially planar with the outer surface for the base plate.

13. The apparatus of claim 9, wherein the base plate material is a thermally conductive material.

14. The apparatus of claim 9, further comprising a thermal interface material between the second surface of the integrated circuit device and the base plate of the heat dissipation device.

15. An electronic system, comprising:
an electronic board; and
an integrated circuit assembly electrically attached to the electronic board, wherein the integrated circuit assembly comprises:
an electronic substrate having a first surface and an opposing second surface;
an integrated circuit device having a first surface and an opposing second surface, wherein the first surface of the integrated circuit device is electrically attached to the first surface of the electronic substrate; and
a heat dissipation device thermally attached to the second surface of the integrated circuit device, wherein the heat dissipation device comprises:
at least one heat pipe; and
a base plate comprising a base plate material, wherein the base plate material at least partially encapsulates the at least one heat pipe.

16. The electronic system of claim 15, further comprising a foundation substrate contacting the at least one heat pipe and contacting the at least one base plate.

17. The electronic system of claim 15, wherein the at least one heat pipe includes an exterior surface having a circumference, wherein on at least a portion of the at least one heat pipe, the base plate material contacts between about 60 and 90 percent of the circumference of the exterior surface of the at least one heat pipe on at least a portion thereof.

18. The electronic system of claim 15, wherein the base plate includes an outer surface and wherein at least a portion of the exterior surface of the at least one heat pipe is substantially planar with the outer surface for the base plate.

19. The electronic system of claim 15, wherein the base plate material is a thermally conductive material.

20. The electronic system of claim 15, further comprising a thermal interface material between the second surface of the integrated circuit device and the base plate of the heat dissipation device.
